(19) United States
(12) Patent Application Publication
(10) Pub. No.: US 2010/0258863 A1
(43) Pub. Date: Oct. 14, 2010

(54) SEMICONDUCTOR DEVICE AND METHOD OF MANUFACTURING THE SAME

(75) Inventor: ATSUSHI KANEKO, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/753,961

(22) Filed: Apr. 5, 2010

(30) Foreign Application Priority Data
Apr. 13, 2009 (JP) 2009-097232

(51) Int. Cl. H01L 29/78; H01L 21/28

(52) U.S. Cl. 257/330; 438/589; 257/E29.262; 257/E21.19

(57) ABSTRACT

A semiconductor device according to the present invention having a vertical MOSFET that includes a first trench that is formed in a semiconductor substrate and includes a gate electrode of the vertical MOSFET embedded therein with a gate insulating film interposed therebetween, a second trench that is connected with the first trench and has a trench width wider than the first trench, a gate pad that is connected with the gate electrode and formed to a sidewall of the second trench with the gate insulating film interposed therebetween, and a gate line that is connected with a sidewall of the gate pad and electrically connects with the gate electrode via the gate pad.

### INCORPORATION BY REFERENCE

This application is based upon and claims the benefit of priority from Japanese patent application No. 2009-097232, filed on Apr. 13, 2009, the disclosure of which is incorporated herein in its entirety by reference.

### BACKGROUND

1. Field of the Invention

The present invention relates to a semiconductor device and a method of manufacturing the same, and particularly to a semiconductor device provided with a vertical MOSFET and a method of manufacturing the same.

2. Description of Related Art

Generally a vertical MOSFET (UMOSFET) is used as a power device such as a power MOSFET (Metal-Oxide-Semiconductor Field-Effect Transistor) to be used as a switch for handling high current and voltage. In the vertical MOSFET, a gate electrode is provided inside a trench and a channel is formed in the vertical direction. Then, a source electrode is formed to one surface of a semiconductor substrate, a drain electrode is formed to the backside of another surface, and a current flows in the vertical direction of the semiconductor substrate. The vertical MOSFET is desired to be highly integrated in order to further reduce the on-resistance and the cost. As the method of high integration of this vertical MOSFET, there is a known method, for example, to completely embed an interlayer dielectric in the trench to narrow the distance inside the trench.

In the vertical MOSFET having the structure to embed the interlayer dielectric in the trench, it is necessary to form a contact hole for pulling out a gate electrode embedded in the trench over a gate trench or from a gate contact. This is a limitation in the outer peripheral design. Therefore, there is a method according to a related art in which the gate electrode is not pulled out but a line or the like is directly connected with the gate electrode in the trench (for example, in Japanese Unexamined Patent Application Publication Nos. 2002-373988 and 2002-368221).

Japanese Unexamined Patent Application Publication No. 2002-373988 discloses a method to increase the outermost peripheral trench width and form a contact for connecting a line in this wide trench. Japanese Unexamined Patent Application Publication No. 2002-368221 discloses a method to form a tiny contact hole for connecting a line immediately above the outermost peripheral trench so as to create a contact with an embedded gate line.

However, the configuration of Japanese Unexamined Patent Application Publication No. 2002-373988 requires a mask process which forms an etchback protection mask for protecting a gate electrode embedded in the wide trench from etchback by photoresist etc. This is explained in detail with reference to FIGS. 6A to 6F. FIGS. 6A to 6F are cross-sectional diagrams illustrating the manufacturing process of the semiconductor device provided with a vertical MOSFET disclosed in Japanese Unexamined Patent Application Publication No. 2002-373988.

As for the vertical MOSFET disclosed in Japanese Unexamined Patent Application Publication No. 2002-373988, an epitaxial layer 101 is formed over a semiconductor substrate which is not illustrated, and a trench 102 is formed to the surface of this epitaxial layer 101. At this time, as illustrated in FIG. 6A, a wide trench 102b with wider trench width than a trench 102a in the cell part is formed in an outermost periphery trench. Next, a gate insulating film 103 is formed over the surface of the epitaxial layer 101. Then, as illustrated in FIG. 6A, the surface in the trench 102a and the surface in the wide trench 102b are covered with the gate insulating film 103. Further, as illustrated in FIG. 6B, a polysilicon layer 104 is formed all over the semiconductor substrate to fill inside the trench 102a and the wide trench 102b.

Next, a mask process for forming an etchback protection mask 105 which is made of photoresist etc. over the polysilicon layer 104 in the wide trench 102b is performed. After that, the polysilicon layer 104 is etched back. At this time, as the polysilicon layer 104 inside the wide trench 102b is protected by the protection mask 105, which is formed before the etchback process, the polysilicon layer 104 is not etched back and remains. In this way, as illustrated in FIG. 6C, a gate electrode 104a, which consists of the polysilicon layer 104 embedded inside the trench 102a, is formed, and at the same time, a gate electrode (gate pad) 104b, which consists of the polysilicon layer 104 embedded inside the wide trench 102b, is formed.

Next, an impurity is introduced into the surface of the epitaxial layer 101 using ion implantation method or the like, and as illustrated in FIG. 6D, a diffusion layer 106 and a source region 107 are formed. Note that FIG. 6 schematically illustrates the formation region of the diffusion layer 106 and the source region 107. Then, an interlayer dielectric 108 is formed to the surface, and a contact hole 109 is opened in the interlayer dielectric 108. To be more specific, a contact hole 109a which reaches the source region 107, and a contact hole 109b which reaches the gate electrode 104b are formed, respectively. Then, as illustrated in FIG. 6E, the gate electrode 104a is covered with the interlayer dielectric 108.

After that, a source line 110 and a gate line 111 are formed over the interlayer dielectric 108. That is, the gate line 111 is formed in the cell part and the source line 110 is formed in the wide trench 102b part, respectively. Then, as illustrated in FIG. 6F, the source line 110 for connecting to the source region 107 via the contact hole 109a, and the gate line 111 for connecting to the gate electrode 104b via the contact hole 109b are formed.

As described above, in the configuration disclosed in Japanese Unexamined Patent Application Publication No. 2002-373988, the polysilicon layer 104 remains in the bottom of the outermost wide trench 102b, thus a masking process is required for forming the protection mask 105 before the etchback process. Therefore, there is a problem that the number of wafer manufacturing process increases.

On the other hand, for the vertical MOSFET disclosed in Japanese Unexamined Patent Application Publication No. 2002-368221, not like the vertical MOSFET disclosed in Japanese Unexamined Patent Application Publication No. 2002-373988, the masking process for forming the etchback protection mask 105 is unnecessary as the wide trench 102b is not formed in the outermost periphery. However, it is necessary to form a contact hole which reaches the outermost periphery trench to be smaller than the size of the trench 102. This is explained in detail with reference to FIGS. 7A to 7F. FIGS. 7A to 7F are cross-sectional diagrams illustrating the manufacturing process of the semiconductor device provided with a vertical MOSFET disclosed in Japanese Unexamined Patent Application Publication No. 2002-368221.

As for the vertical MOSFET disclosed in Japanese Unexamined Patent Application Publication No. 2002-368221, an epitaxial layer 101 is formed over a semiconductor substrate which is not illustrated, and a trench 102 is formed to the surface of this epitaxial layer 101. At this time, not like the trench 102 disclosed in Japanese Unexamined Patent Application Publication No. 2002-373988, as illustrated in FIG. 7A, a trench 102c, which has a narrow trench width similar to the trench 102a in the cell part, is formed in the outermost peripheral trench. Next, a gate insulating film 103 is formed to the surface of the epitaxial layer 101. Then, as illustrated in FIG. 7A, the surface in the trench 102a and the surface in the trench 102c are covered with the gate insulating film 103. Moreover, as illustrated in FIG. 7B, a polysilicon layer 104 is formed all over the semiconductor substrate to fill inside the trench 102a and the wide trench 102c.

After that, the polysilicon layer 104 is etched back. At this time, as the outermost peripheral trench 102c includes a narrow trench width in a similar way as the trench 102a, the polysilicon layer 104 in the trench 102c remains in a similar way as the polysilicon layer 104 in the trench 102a. In this way, as illustrated in FIG. 7C, a gate electrode 104a which is composed of the polysilicon layer 104 is formed inside the trench 102a, and a gate electrode (gate pad) 104c which is composed of the polysilicon layer 104 is formed inside the trench 102c.

Next, an impurity is introduced into the surface of the epitaxial layer 101 using ion implantation method or the like, and as illustrated in FIG. 7D, a diffusion layer 106 and a source region 107 are formed. Note that FIG. 7D schematically illustrates the formation region of the diffusion layer 106 and the source region 107. Then, an interlayer dielectric 108 is formed to the surface, and a contact hole 109 is opened in the interlayer dielectric 108. To be more specific, a contact hole 109a which reaches the source region 107, and a contact hole 109c which reaches the gate electrode 104c are formed, respectively. The opening size of the contact hole 109c formed at this time must be smaller than the contact hole 109b disclosed in Japanese Unexamined Patent Application Publication No. 2002-373988. Accordingly, the contact hole 109c having a smaller opening size than the trench 102 is formed. Then, the configuration illustrated in FIG. 7E is completed.

After that, a source line 110 and a gate line 111 are formed over the interlayer dielectric 108. Accordingly, the gate line 111 is formed in the cell part and the source line 110 is formed in the wide trench 102b part, respectively. Then, as illustrated in FIG. 7F, the source line 110 for connecting to the source region 107 via the contact hole 109a, and the gate line 111 for connecting to the gate electrode 104b via the contact hole 109b are formed.

Thus, in the configuration disclosed in Japanese Unexamined Patent Application Publication No. 2002-368221, the contact hole 109c must be formed smaller than the trench 102. Generally, in the vertical MOSFET, the trench 102 is designed to be the finest, and in order to open a finer contact hole 109c, a masking and etching process must be finer. Therefore, the present inventor has found a problem that there is a problem of leading to increase the cost. Moreover, as the contact hole 109c is small, the gate resistance increases and thereby leading to problems such as reducing the operation speed and efficiency in the high switching operation.

### SUMMARY

An exemplary aspect of the present invention is a semiconductor device having a vertical MOSFET that includes a first trench that is formed in a semiconductor substrate and includes a gate electrode of the vertical MOSFET embedded therein with a gate insulating film interposed therebetween, a second trench that is connected with the first trench and has a trench width wider than the first trench, a gate pad that is connected with the gate electrode and formed to a sidewall of the second trench with the gate insulating film interposed therebetween, and a gate line that is connected with a sidewall of the gate pad and electrically connects with the gate electrode via the gate pad. This achieves the configuration in which the gate pads formed respectively to opposing sidewalls in the second trench are apart from each other, which are provided to obtain a contact with the gate electrode and the gate line. This enables to reduce the cost and simplify the wafer manufacturing process.

Another exemplary aspect of the present invention is a method of manufacturing a semiconductor device having a vertical MOSFET that includes forming a first trench and a second trench in a semiconductor substrate, where the second trench is connected with the first trench and includes a trench width wider than the first trench, forming a gate insulating film that covers a surface inside the first trench and a surface inside the second trench, forming a gate electrode and a gate pad, where the gate electrode is embedded inside the first trench with the gate insulating film interposed therebetween, and the gate pad is provided to a sidewall of the second trench with the gate insulating film interposed therebetween, and forming a gate line that connects with a sidewall of the gate pad. This achieves the configuration in which the gate pads formed respectively to opposing sidewalls in the second trench are apart from each other, which are provided to obtain a contact with the gate electrode and the gate line. This enables to reduce the cost and simplify the wafer manufacturing process.

The present invention provides a semiconductor device that enables to easily obtain a contact with the gate electrode, and a method of manufacturing the same.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a top view of a semiconductor device according to this exemplary embodiment;

FIG. 2 is a cross-sectional diagram taken along the line II-II of FIG. 1;

FIG. 3 is a perspective view from the cross-section II-II of FIG. 1;

FIGS. 4A to 4F are cross-sectional diagrams illustrating the manufacturing process of the semiconductor device according to this exemplary embodiment;

FIG. 5 is a cross-sectional diagram of the semiconductor device according to another example of this exemplary embodiment;

FIGS. 6A to 6F are cross-sectional diagrams illustrating the manufacturing process of a semiconductor device according to a prior art; and

FIGS. 7A to 7F are cross-sectional diagrams illustrating the manufacturing process of a semiconductor device according to a prior art.

### DETAILED DESCRIPTION OF THE EXEMPLARY EMBODIMENTS

Hereinafter, an exemplary embodiment of the present invention is described with reference to the drawings. For clarity of explanation, the following descriptions and drawings are omitted and simplified as appropriate. Moreover, for clarity of explanation, repeated explanation is omitted as necessary. Note that the same components in the drawings are denoted by the same reference numerals and the explanation thereof is omitted as appropriate.

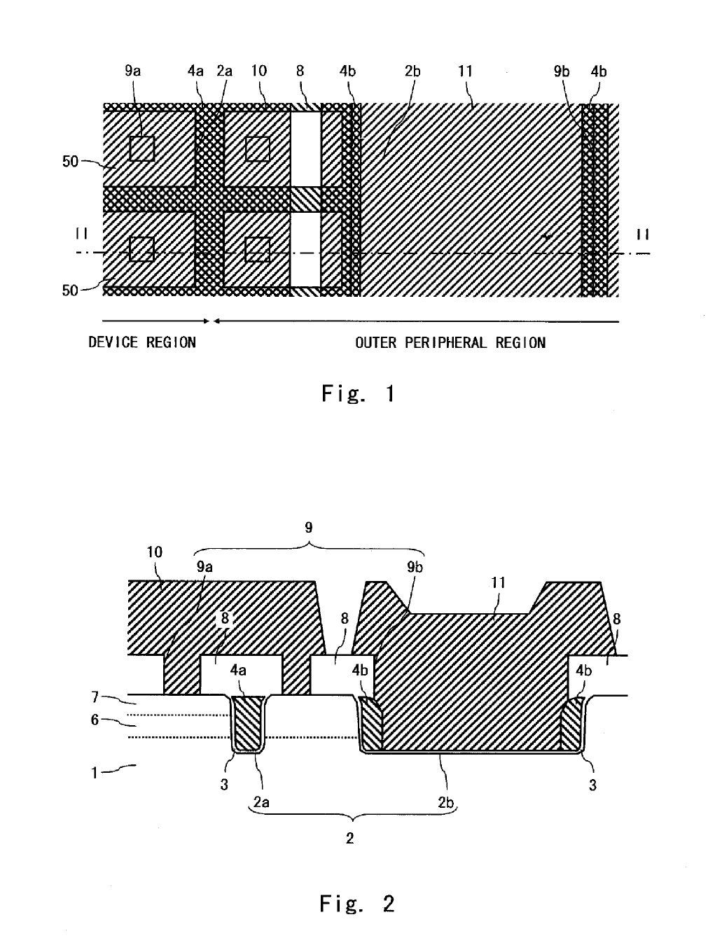

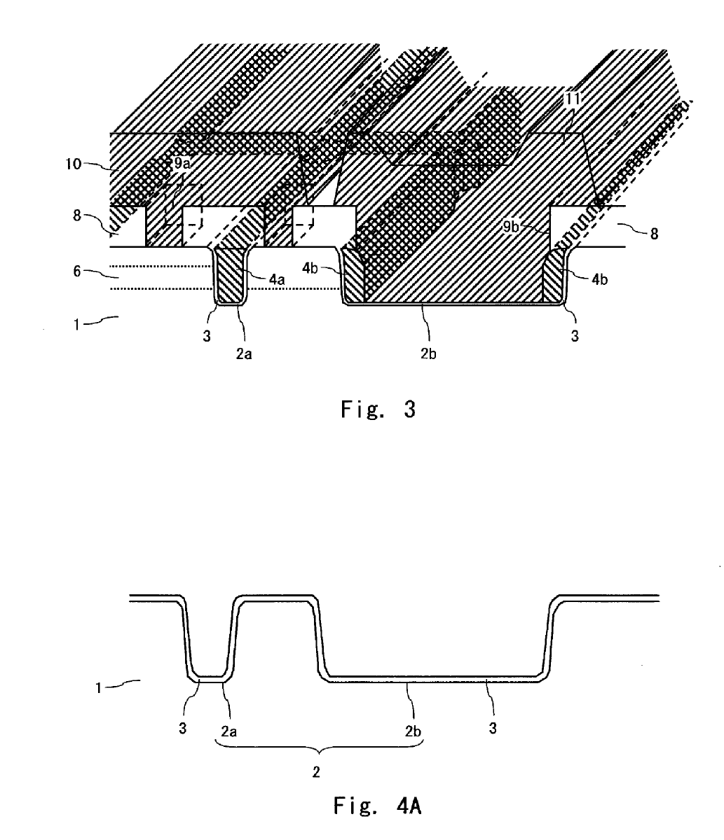

First, the configuration of a semiconductor device according to this exemplary embodiment is described with reference to FIGS. 1 to 3. FIG. 1 is a top view of the semiconductor device according to this exemplary embodiment. FIG. 2 is a cross-sectional diagram taken along the line II-II of FIG. 1. FIG. 3 is a perspective view from the cross-section II-II of FIG. 1.

The semiconductor device of this exemplary embodiment is provided with a semiconductor substrate of a first conductivity type (for example, n⁺ type). The semiconductor substrate is made of a semiconductor material generally used, such as silicon. As illustrated in FIG. 1, this semiconductor substrate is provided with a device region including a plurality of vertical MOSFETs 50, and an outer peripheral region provided outside the device region. For example, the plurality of vertical MOSFETs 50 are arranged in matrix in the device region. Note that FIG. 1 illustrates only a part of the semiconductor device, however the outer peripheral region is formed to surround the device region, for example.

As illustrated in FIGS. 2 and 3, an epitaxial layer 1 of a first conductivity type (for example, n⁻ type) that is made of a semiconductor material, such as silicon, is formed over the surface of the semiconductor substrate. The epitaxial layer 1 functions as a drain of the vertical MOSFET 50 together with the semiconductor substrate.

A diffusion layer 6 of a second conductivity type (for example, p type) is provided to a surface layer of the epitaxial layer 1. A trench (trench 2) which reaches inside the epitaxial layer 1 from the surface of the diffusion layer 6 is formed in the diffusion layer 6. That is, the trench 2 which reaches to a position deeper than the diffusion layer 6 is formed in the epitaxial layer 1. As this trench 2, there are a lattice-shaped trench 2a provided mainly in the device formation region, and a wide trench 2b with wide trench width provided in the outer peripheral region.

According to this exemplary embodiment, there is the trench (a first trench) 2a placed regularly at a predetermined interval, and the wide trench (a second trench) 2b with wider trench width than the trench 2a. The trench 2a is mainly provided in the device formation region, and ends in the outer peripheral region, for example. In this example, the lattice-shaped trench 2a is formed. On the other hand, the wide trench 2b is provided in the outer peripheral region. Then, the wide trench 2b is formed to be connected with the trench 2a. As illustrated in FIGS. 1 to 4, for example, the wide trench 2b is formed as the trench 2 provided in the outermost periphery, for example. Therefore, for example, the lattice-shaped trench 2a is formed in a region inside the frame-like wide trench 2b to be connected with the wide trench 2b.

There are a plurality of cells defined over the semiconductor substrate by the trench 2a. That is, the diffusion layer 6 is separated into a plurality of rectangular shape islands placed at the predetermined interval by the trench 2a. The source region 7 of a first conductivity type (for example, n⁺ type) is selectively formed to the surface of the diffusion layer 6. In FIGS. 2 and 3, the diffusion layer 6 and the source region 7 are illustrated schematically, however the source region 7 has band-like planar shape along the periphery of the diffusion layer 6. Note that the source region 7 is not formed in an outermost periphery cell, but only the diffusion layer 6 is formed therein.

A gate electrode 4a is formed inside the trench 2a with a gate insulating film 3 interposed therebetween. The gate electrode 4a is embedded in the trench 2a. The surface of the gate electrode 4a is formed to a position lower than the surface of the diffusion layer 6 of the epitaxial layer 1. The gate insulating film 3 covers inner walls of the trenches 2a and 2b, and also extends over the diffusion layer 6 of the epitaxial layer 1. On the other hand, a gate electrode (gate pad) 4b is formed to the sidewall inside the trench 2b with the gate insulating film 3 interposed therebetween. That is, the sidewall-like gate electrode 4b is formed to the inner wall surface of the trench 2b. Therefore, the gate electrode 4b is not provided in the region away from the sidewall of the trench 2b and only provided near the sidewall. The gate electrodes 4a and 4b are made of a conductive material, such as n type polysilicon, for example.

An interlayer dielectric 8 is provided over the epitaxial layer 1 to cover the gate electrode 4a. The interlayer dielectric 8 is formed to fill inside the trench 2a over the gate electrode 4a. A plurality of contact holes 9 are formed in the interlayer dielectric 8. To be more specific, a contact hole 9a which reaches the diffusion layer 6 and the source region 7, and a contact hole 9b which is provided over the trench 2b are formed. An opening size of the contact hole 9b is formed to be smaller than that of the trench 2b, and larger than the interval between the gate electrodes 4b, which are provided to the sidewall of the trench 2b. That is, the sidewall of the contact hole 9b is formed to be over the gate electrode 4b. Therefore, at least a part of the upper surface of the gate electrode 4b is covered with the interlayer dielectric 8, however the opposite sidewall to the sidewall contacting the gate insulating film 3 is not covered with the interlayer dielectric 8. As described so far, the interlayer dielectric 8 is provided which includes the contact hole 9b reaching the gate insulating film 3 of the bottom of the trench 2b and the sidewall of the gate electrode 4b. Note that the contact hole 9a is provided for every cell.

Over the interlayer dielectric 8, the source line 10 and the gate line 11, which are made of a conductive metal layer or the like of a predetermined pattern shape, are formed. The source line 10 covers almost all over the device formation region, and is electrically connected with the diffusion layer 6 and the source region 7 via the contact hole 9a. The gate line 11 is arranged in the outer peripheral region, and covers the contact hole 9b. The gate line 11 is formed to fill inside the trench 2b. That is, the gate line 11 is formed to fill inside the trench 2b from above the interlayer dielectric 8. The gate line 11 contacts the gate insulating film 3 at the bottom of the trench 2b. In the trench 2b, the gate line 11 contacts the sidewall of the gate electrode 4b, and thus the gate line 11 and the gate electrode 4b are electrically connected. In this way, the gate line 11 and the gate electrode 4a are electrically connected by the gate electrode 4b provided in the trench 2b. The gate line 11 and epitaxial layer 1 are insulated by the gate insulating film 3.

The plurality of MOSFETs 50 which are connected in parallel are composed of the abovementioned semiconductor substrate, the epitaxial layer 1 (that is, a drain), the source region 7, and the gate electrode 4a. These vertical MOSFETs 50 are formed to correspond to each cell in the device formation region where the source region 7 is provided. Note that a drain electrode which is not illustrated may be provided to the backside of the semiconductor substrate.

Note that a pn junction is formed between the epitaxial layer 1 and the diffusion layer 6. The epitaxial layer 1 functions also as an electric field reducing layer for reducing the electric field applied to this pn junction.

As described so far, a semiconductor device of this exemplary embodiment is a semiconductor device having a vertical MOSFET 50 that includes a trench 2a (first trench) that is formed in a semiconductor substrate and includes a gate electrode 4a of the vertical MOSFET 50 embedded therein with a gate insulating film 3 interposed therebetween, a trench 2b (second trench) that is connected with the trench 2a and has a trench width wider than the trench 2a, a gate electrode 4b (gate pad) that is connected with the gate electrode 4a and formed to a sidewall of the trench 2b with the gate insulating film 3 interposed therebetween, and a gate line 11 that is connected with a sidewall of the gate electrode 4b and electrically connects with the gate electrode 4a via the gate electrode 4b.

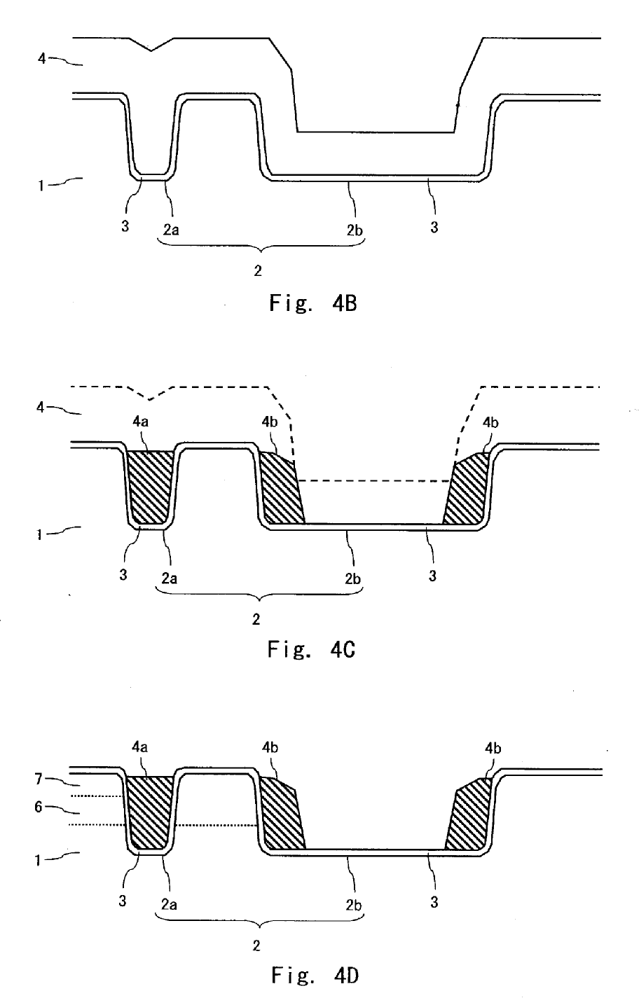

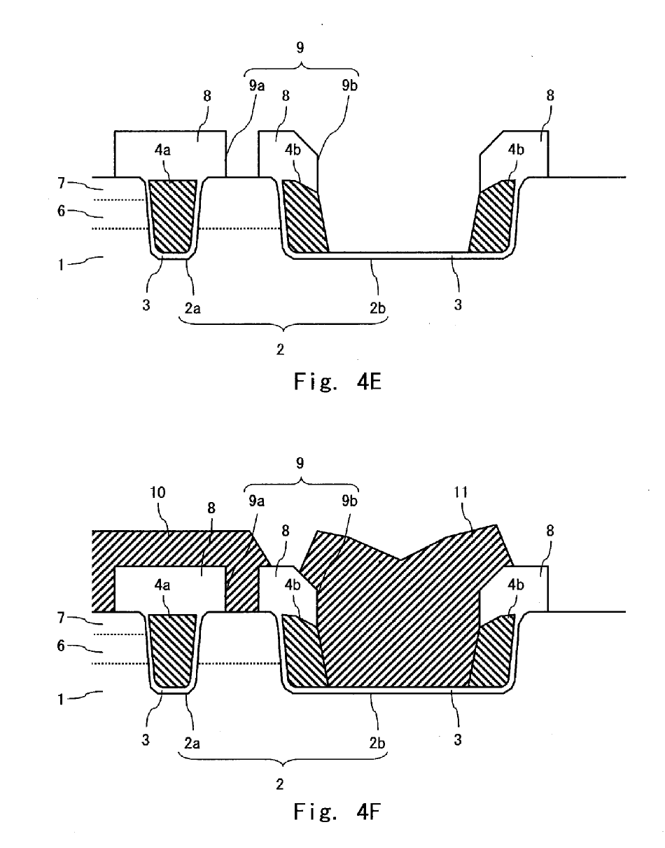

Next, the manufacturing method of the semiconductor device formed as described above is explained with reference to FIGS. 4A to 4F. FIGS. 4A to 4F are cross-sectional diagrams illustrating the manufacturing process of the semiconductor device according to this exemplary embodiment. Note that FIGS. 4D to 4F schematically illustrate the formation region of the diffusion layer 6 and the source region 7, in a similar way as FIGS. 2 and 3.

First, an epitaxial layer 1 is grown over the entire surface of the semiconductor substrate which is not illustrated. Then, the trench 2 is formed in the surface of this epitaxial layer 1. At this time, in this exemplary embodiment, the trench 2b is formed regularly at a predetermined interval, and the wide trench 2b with wider trench width than the trench 2a is formed. In this example, the trench 2a is formed in lattice, and the wide trench 2b is formed in the outermost periphery. Moreover, the gate insulating film 3 is formed over the surface of the epitaxial layer 1. Then, as illustrated in FIG. 4A, the surface in the trench 2a and the surface in the wide trench 2b are covered with the gate insulating film 3.

Next, as illustrated in FIG. 4B, the polysilicon layer 4 is deposited all over the semiconductor substrate to fill inside the trench 2a and also to cover the trench 2b.

Then, the polysilicon layer 4 is etched back. At this time, in this exemplary embodiment, the etchback is performed, provided that the polysilicon layer 4 is embedded in the trench 2a. Then, as for the polysilicon layer 4 in the wide trench 2b, the thin part formed over the bottom surface of the wide trench 2b is removed by the etchback, and the thick part formed to the sidewall remains. In this way, as illustrated in FIG. 4C, the gate electrode 4a made of polysilicon is formed inside the trench 2a, and also the gate electrode 4b made of polysilicon is formed to the sidewall surface of the trench 2b. Note that this etchback process slightly etches the gate insulating film 3 of the bottom surface of the wide trench 2b. Therefore, it is necessary to form the gate insulating film 3 to be thick in advance in consideration of the etched thickness, and adjust the etchback of the polysilicon layer 4 in the condition that the gate insulating film 4 to be hardly etched.

Next, an impurity is introduced into the surface of the epitaxial layer 1 using ion implantation method or the like, and as illustrated in FIG. 4D, the diffusion layer 6 and the source region 7 are formed. To be more specific, a p type impurity such as boron (B) is implanted to form the diffusion layer 6 over the surface of the epitaxial layer 1. Next, after performing a mask process to form a mask pattern over the diffusion layer 6, an n type impurity, such as arsenic (As), is implanted to form the source region. Note that at the time of forming the diffusion layer 6, the substrate is masked so that the diffusion layer is not formed to the bottom surface of the trench 2b.

After that, the interlayer dielectric 8 is formed over the entire semiconductor substrate. Next, the contact hole 9 is opened in the interlayer dielectric 8. To be more specific, a contact hole 9a is formed in the cell part, and a contact hole 9b is formed over the trench 2b. At this time, the contact hole 9b is formed in a way that the interlayer dielectric 8 remains over the top surface of the gate electrode 4b in the trench 2b, and the sidewall surface of the gate electrode 4b, and the gate insulating film 3 in the part not covered with the gate electrode 4b at the bottom surface of the trench 2b are exposed. Further, the contact hole 9a is formed so that at least a part of the diffusion layer 6 and the source region 7 is exposed. Then, the gate electrode 4a is covered with the interlayer dielectric 8, to be the configuration illustrated in FIG. 4E.

Then, the source line 10 and the gate line 11 are formed over the interlayer dielectric 8. That is, by the same conductive metal layer, the source line 11 is formed in the cell part, and the gate line 11 is formed in the wide trench 2b, respectively. Accordingly, as illustrated in FIG. 4F, the source line 10 for connecting the source region 7 via the contact hole 9a, and the gate line 11 for connecting the gate electrode 4b via the contact hole 9b are formed. The semiconductor device according to this exemplary embodiment is completed through the above process.

As described so far, a method of manufacturing a semiconductor device of this exemplary embodiment is a method of manufacturing a semiconductor device having a vertical MOSFET that includes forming a trench 2a (first trench) and a trench 2b (second trench) in a semiconductor substrate, where the trench 2b is connected with the trench 2a and includes a trench width wider than the trench 2a, forming a gate insulating film 3 that covers a surface inside the trench 2a and a surface inside the trench 2b, forming a gate electrode 4a and a gate electrode 4b (gate pad), where the gate electrode 4a is embedded inside the trench 2a with the gate insulating film 3 interposed therebetween, and the gate electrode 4b is provided to a sidewall of the trench 2b with the gate insulating film 3 interposed therebetween, and forming a gate line 11 that connects with a sidewall of the gate electrode 4b.

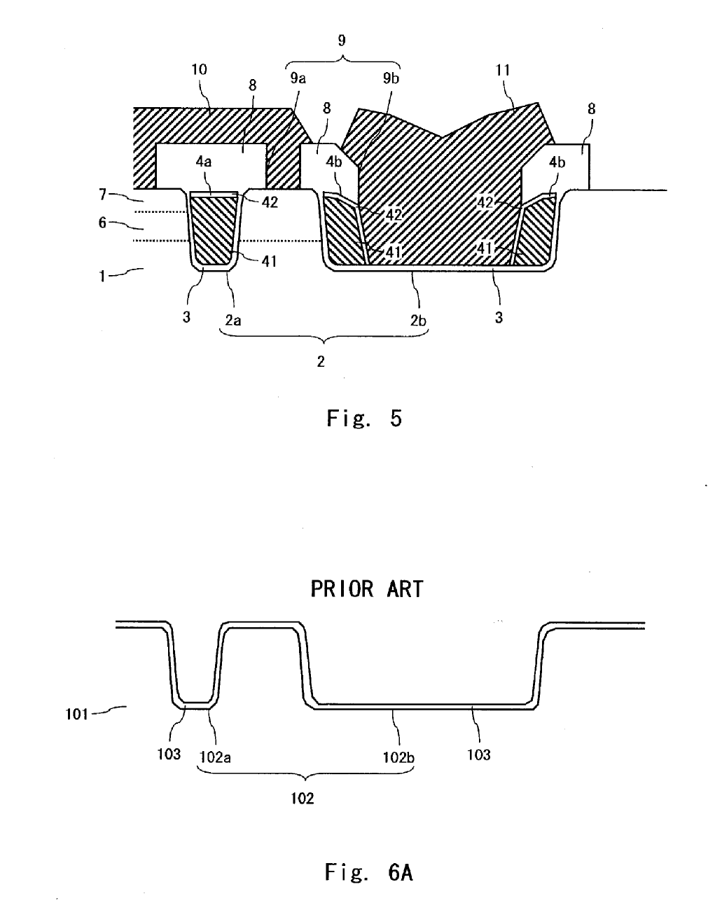

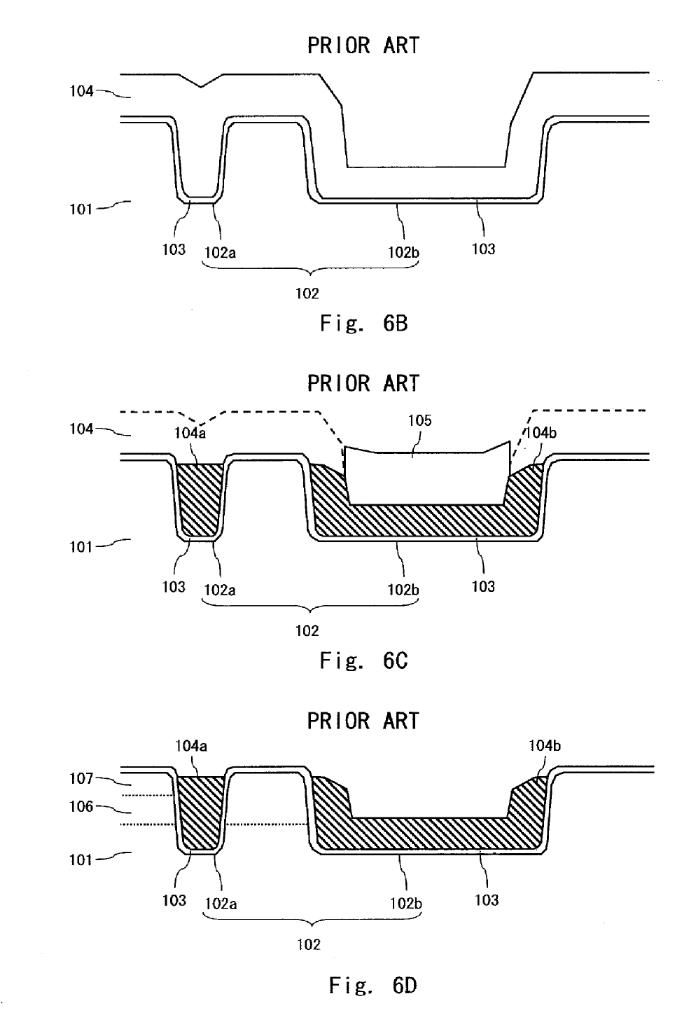

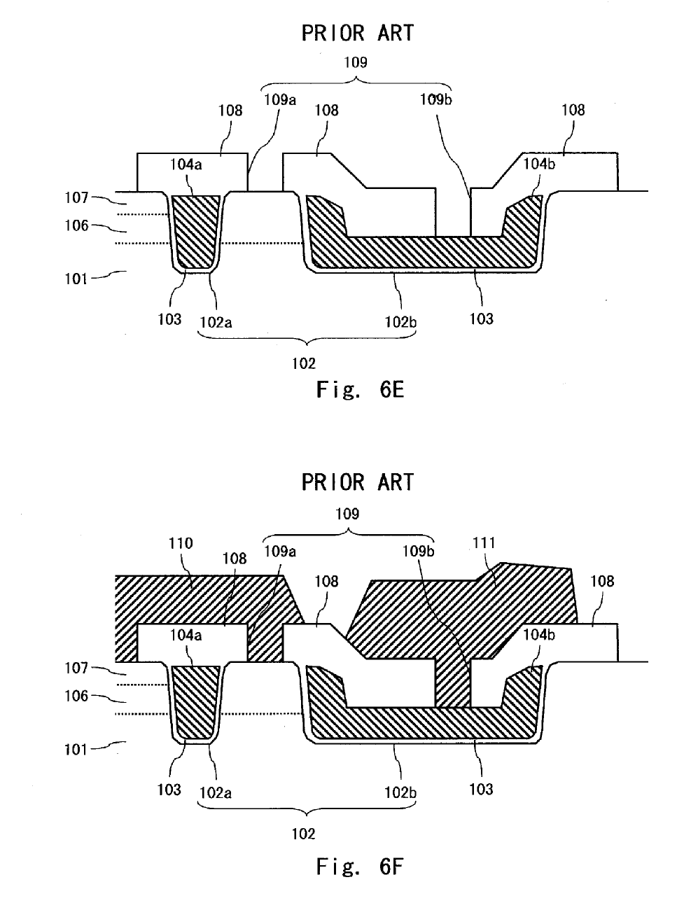

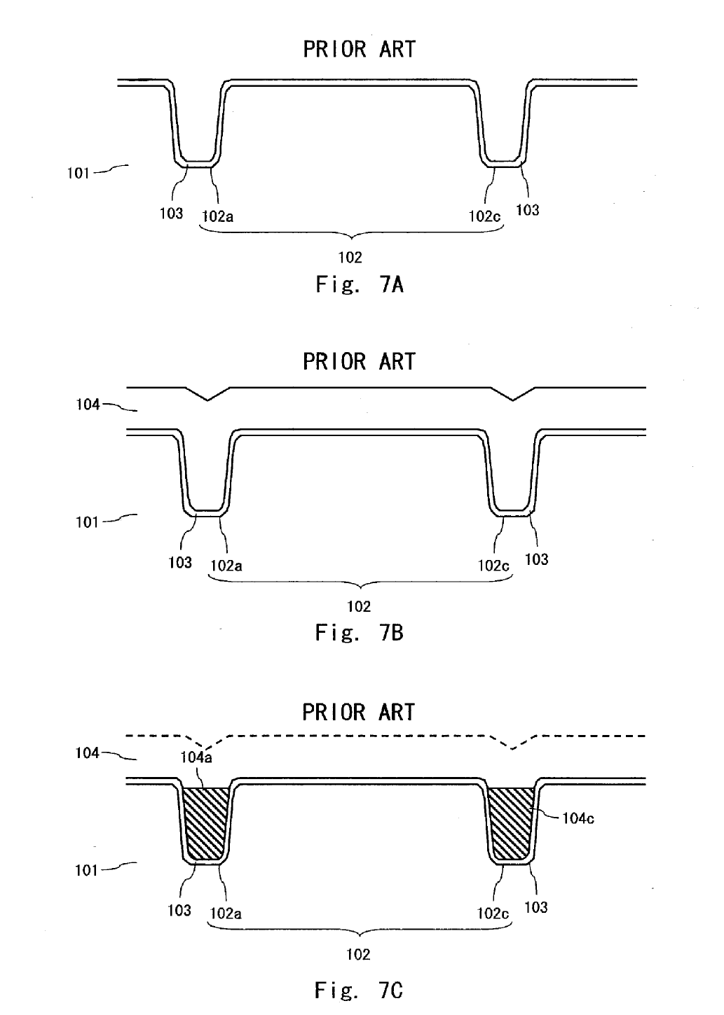

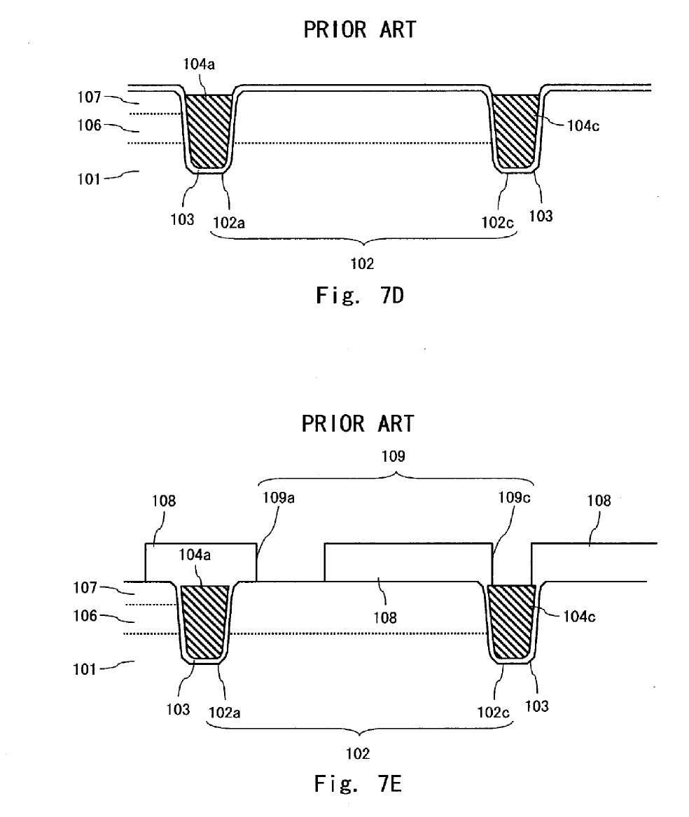

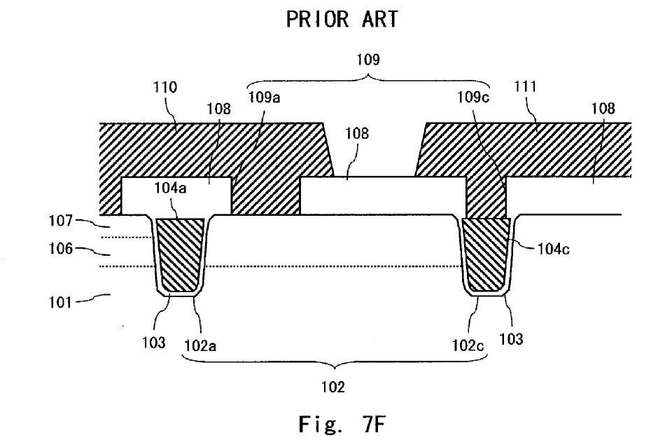

Note that this exemplary embodiment explained an example for forming the gate electrodes 4a and 4b with polysilicon, however the gate electrodes 4a and 4b may be formed by polysilicon with a polycide surface. FIG. 5 is a cross-sectional diagram of a semiconductor device according to another example of this exemplary embodiment. As illustrated in FIG. 5, the gate electrodes 4a and 4b may have the laminated structure having a silicide 42 laminated over the surface of the polysilicon 41. In order to form the gate electrodes 4a and 4b having such laminated structure, a polysilicon may be turned into polycide after the etchback of the polysilicon layer 4. This reduces the resistance of the gate electrodes 4a and 4b, and the contact resistance between the gate electrode 4b and the gate line 11. Therefore, this reduces the gate resistance and improves the switching speed.

As described above, in this exemplary embodiment, sidewall-like gate electrode 4b is formed to the sidewall of the trench 2b having wider trench width than the trench 2a of the device formation region, so that the gate line 11 is in contact with the gate electrode 4b at its sidewall. This eliminates the need to protect the polysilicon layer 4 over the bottom surface of the wide trench 2b from etchback, and therefore the mask process for forming the etchback protection mask 105 becomes unnecessary. Thus this enables to reduce the cost and simplify the wafer manufacturing process. Moreover, as the trench width of the wide trench 2b is wider than the trench 2a, it is not necessary to reduce the opening size of the contact hole 9b for connecting the gate line 11 to the gate electrode 4b than the trench 2b. Therefore, it is possible to reduce the cost of the forming process of the contact hole 9. Further, as the opening size of the contact hole 9b can be larger than in a related art, the resistance of the gate line 11 can be reduced, thereby enabling to expect an improvement in the characteristics of high speed switching operation. Therefore, this exemplary embodiment provides a semiconductor device that enables to easily obtain a contact with the gate electrode and a manufacturing method for the same.

Note that the present invention is not limited to the above exemplary embodiment, but may be changed within the scope and the sprit of the present invention. For example, the above exemplary embodiment explained an example of forming the wide trench 2b in the outermost periphery of the lattice-shaped trench 2a. However the arrangement of the wide trench 2b is not limited to this, but a similar trench 2a as the lattice-shaped trench 2a may be formed to further outside of the wide trench 2b. For example, the wide trench 2b may be placed between the lattice-shaped trench 2a and another lattice-shaped trench 2a. In this case, an outer peripheral region will be placed between device formation regions. The point is, the wide trench 2b may be formed in a position where a gate contact is provided in order to obtain an electric contact with the gate electrode 4a in the cell part, and the position to place the gate contact may be determined as appropriate.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device including a vertical MOSFET comprising:
a first trench formed in a semiconductor substrate and including a gate electrode of the vertical MOSFET embedded therein with a gate insulating film interposed therebetween;
a second trench connected with the first trench and having a trench width wider than the first trench;
a gate pad connected with the gate electrode and formed to a sidewall of the second trench with the gate insulating film interposed therebetween; and
a gate line connected with a sidewall of the gate pad and electrically connected with the gate electrode via the gate pad.

2. The semiconductor device according to claim 1, further comprising an interlayer dielectric formed over the semiconductor substrate and including a contact hole that reaches the gate insulating film of a bottom surface of the second trench and the sidewall of the gate pad,
wherein the gate line is formed to fill inside the second trench from above the interlayer dielectric.

3. The semiconductor device according to claim 1, wherein the gate electrode and the gate pad are formed of polysilicon.

4. The semiconductor device according to claim 1, wherein the gate electrode and the gate pad are formed of polysilicon with a polycide surface.

5. A method of manufacturing a semiconductor device including a vertical MOSFET, the method comprising:
forming a first trench and a second trench in a semiconductor substrate, the second trench being connected with the first trench and including a trench width wider than the first trench;
forming a gate insulating film that covers a surface inside the first trench and a surface inside the second trench;
forming a gate electrode and a gate pad, the gate electrode being embedded inside the first trench with the gate insulating film interposed therebetween, and the gate pad being provided to a sidewall of the second trench with the gate insulating film interposed therebetween; and
forming a gate line that connects with a sidewall of the gate pad.

6. The method of manufacturing a semiconductor device according to claim 5, wherein the gate electrode and the gate pad are formed by depositing a conductive layer for forming the gate electrode of the vertical MOSFET over the gate insulating film and then etching back the conductive layer.

7. The method of manufacturing a semiconductor device according to claim 6, wherein the conductive layer is polysilicon.

8. The method of manufacturing a semiconductor device according to claim 7, further comprising turning a surface of the polysilicon into polycide after the etchback of the conductive layer.

9. The method of manufacturing a semiconductor device according to claim 5, further comprising forming an interlayer dielectric before forming the gate line, the interlayer dielectric including a contact hole that reaches the gate insulating film of a bottom surface of the second trench and a sidewall of the gate pad,
wherein the gate line is connected with the sidewall of the gate pad by forming the gate line to fill inside the second trench from above the interlayer dielectric.
